(19) United States
(12) Patent Application Publication
(10) Pub. No.: US 2025/0212388 A1
(43) Pub. Date: Jun. 26, 2025

(54) SEMICONDUCTOR DEVICE

(71) Applicant: Samsung Electronics Co., Ltd., Suwon-si (KR)

(72) Inventors: Changsik KIM, Suwon-si (KR); Jihoon CHANG, Suwon-si (KR); Jihee JUN, Suwon-si (KR)

(73) Assignee: Samsung Electronics Co., Ltd., Suwon-si (KR)

(21) Appl. No.: 18/973,417

(22) Filed: Dec. 9, 2024

(30) Foreign Application Priority Data
Dec. 20, 2023 (KR) 10-2023-0187515

(51) Int. Cl. H10B 12/00

(52) U.S. Cl. CPC H10B 12/315; H10B 12/05

(57) ABSTRACT

In order to fulfill excellent performance and improved economic efficiency, it may be required to increase the integration degree of semiconductor devices. The electrical characteristics and product reliability of the semiconductor device may be improved by arranging an intermediate insulating layer between a channel layer and a gate insulating layer in a semiconductor device including a vertical channel transistor.

### CROSS-REFERENCE TO RELATED APPLICATIONS

This application is based on and claims priority under 35 U.S.C. § 119 to Korean Patent Application No. 10-2023-0187515, filed on Dec. 20, 2023, in the Korean Intellectual Property Office, the disclosure of which is incorporated by reference herein in its entirety.

### BACKGROUND

Various example embodiments of the inventive concepts relate to a semiconductor device, and more particularly, to a semiconductor device including a vertical channel transistor.

In order to meet excellent performance and improved economic efficiency, it may be required to increase the integration degree of semiconductor devices. In particular, the degree of integration of memory devices is an important factor in determining the economic feasibility of a product. Since the integration degree of a two-dimensional memory device is mainly determined by the area occupied by unit memory cells, the level of technology for forming fine patterns is a decisive factor. However, as more expensive equipment may be required to form fine patterns, the area of the chip die is still limited. Thus, the integration degree of two-dimensional memory devices is still increasing to overcome the limitations of the area of the chip die. Accordingly, the demand for semiconductor devices including vertical channel transistors (VCT) is increasing.

### SUMMARY

Various example embodiments of the inventive concepts provide a semiconductor device having improved electrical characteristics and improved product reliability.

The objective to be solved by various example embodiments of the inventive concepts are not limited to the objectives mentioned above, and other objectives not mentioned will be clearly understood by those skilled in the art from the description below.

According to various example embodiments the inventive concepts, there is provided a semiconductor device including a bit line extending in a first horizontal direction on a substrate, a channel layer on the bit line and penetrating into a portion of the bit line, including an oxide semiconductor material including indium (In), and the channel layer having an inner wall and an outer wall, a gate insulating layer on one side of an inner wall of the channel layer, and the gate insulating layer having an inner wall and an outer wall, an intermediate insulating layer between the inner wall of the channel layer and the outer wall of the gate insulating layer and including an insulating material that is different from that of the gate insulating layer, a word line on the inner wall of the gate insulating layer and extending in a second horizontal direction intersecting with the first horizontal direction, and a contact layer on a top surface of the channel layer and a top surface of the gate insulating layer. The intermediate insulating layer is formed only on a portion of the outer wall of the gate insulating layer.

According to other example embodiments of the inventive concepts, there is provided a semiconductor device including a bit line extending in a first horizontal direction on a substrate, a channel layer having a U-shape and penetrating into a portion of the bit line, including InGaZnOₓ (IGZO), and having an inner wall and an outer wall, a gate insulating layer on one side of the inner wall of the channel layer, comprising a high-k dielectric material, and the gate insulating layer having an inner wall and an outer wall, an intermediate insulating layer between the inner wall of the channel layer and the outer wall of the gate insulating layer, and the intermediate insulating layer including at least one of silicon oxide and silicon oxynitride, a word line on the inner wall of the gate insulating layer and extending in a second horizontal direction intersecting with the first horizontal direction, and a contact layer on a top surface of the channel layer and a top surface of the gate insulating layer.

According to other example embodiments of the inventive concepts, there is provided a semiconductor device including a bit line extending in a first horizontal direction on a substrate, a mold layer covering the bit line on the substrate and the mold layer having a mold opening, a channel layer on an inner wall of the mold opening, having a bottom portion penetrating into the bit line and a sidewall portion extending in a vertical direction on the inner wall of the mold opening, and the channel layer including InGaZnOₓ (IGZO), a gate insulating layer within the mold opening, on the channel layer, and the gate insulating layer comprising a high-k dielectric material, an intermediate insulating layer within the mold opening, between the channel layer and the gate insulating layer, and the intermediate insulating layer comprising at least one of silicon oxide and silicon oxynitride, a word line within the mold opening, on the gate insulating layer, and extending in a second horizontal direction intersecting with the first horizontal direction, a contact layer on a top surface of the channel layer and a top surface of the gate insulating layer, and a capacitor structure on the contact layer. The intermediate insulating layer is formed only in a portion between the channel layer and the gate insulating layer.

### BRIEF DESCRIPTION OF THE DRAWINGS

Various example embodiments will be more clearly understood from the following detailed description taken in conjunction with the accompanying drawings in which:

FIG. 1 illustrates a layout of a semiconductor device according to various example embodiments;

FIG. 2 illustrates an enlarged layout of a portion of a cell array area of FIG. 1;

FIG. 3 is a cross-sectional view taken along line A1-A1′ in FIG. 2;

FIGS. 4 and 5 are cross-sectional views illustrating a semiconductor device according to other example embodiments;

FIGS. 6 to 16 are cross-sectional views illustrating a method of manufacturing a semiconductor device, according to a process sequence, according to various example embodiments; and

FIG. 17 is a structural diagram illustrating a system including a semiconductor device, according to various example embodiments.

### DETAILED DESCRIPTION

Hereinafter, various example embodiments of the inventive concepts will be described in detail with reference to the attached drawings.

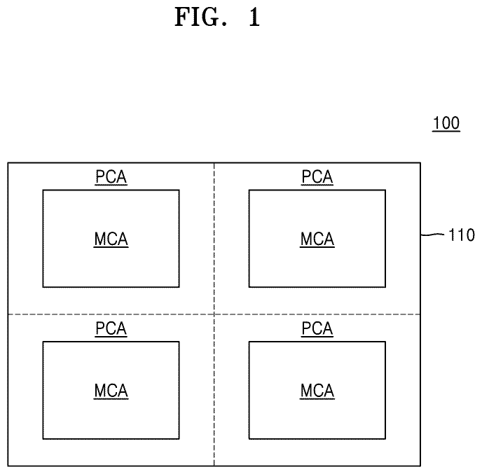

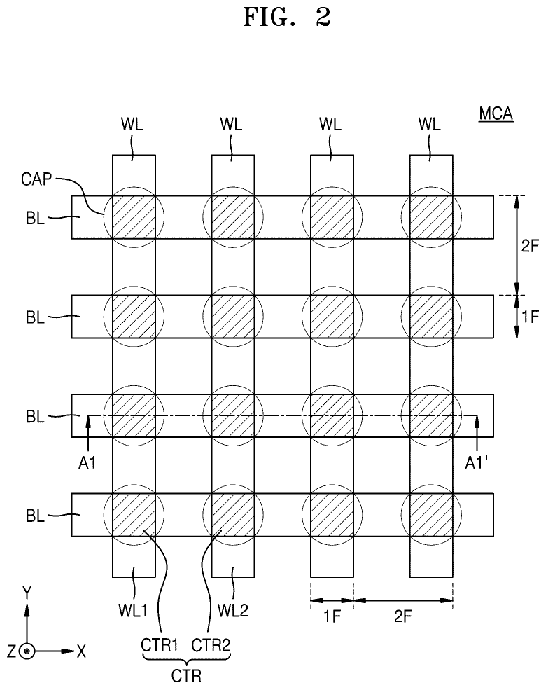

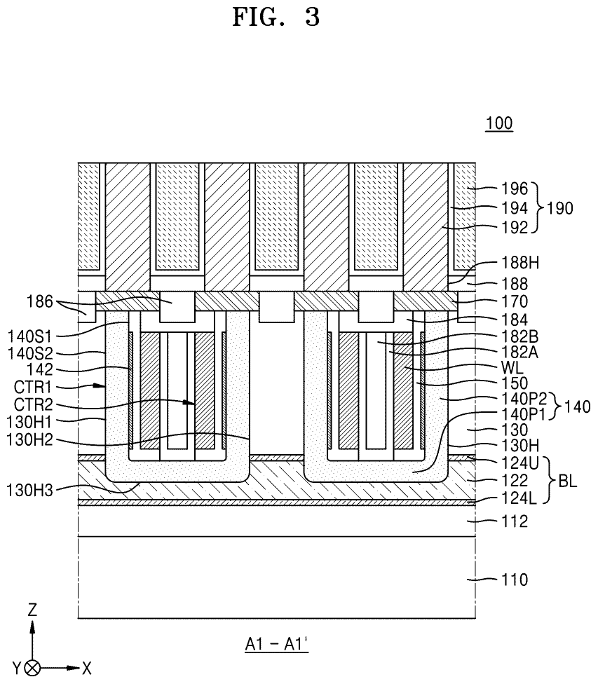

FIG. 1 illustrates a layout of a semiconductor device according to various example embodiments. FIG. 2 illustrates an enlarged layout of a portion of a cell array area of FIG. 1. FIG. 3 is a cross-sectional view taken along line A1-A1′ in FIG. 2.

Referring to FIGS. 1 to 3 together, a semiconductor device 100 may include a substrate 110 including a cell array area MCA and a peripheral circuit area PCA.

In some example embodiments, the cell array area MCA may be a memory cell area of a dynamic random access memory (DRAM) device, and the peripheral circuit area PCA may be a core area or a peripheral circuit area of a DRAM device. For example, the peripheral circuit area PCA may include a peripheral circuit transistor (not shown) transmitting signals and/or power to a memory cell array included in the cell array area MCA.

In some example embodiments, the peripheral circuit transistor (not shown) may form various circuits such as a command decoder, control logic, an address buffer, a row decoder, a column decoder, a sense amplifier, and a data input/output circuit.

In the cell array area MCA of a substrate 110, a plurality of bit lines BL extending in a first horizontal direction X and a plurality of word lines WL extending in a second horizontal direction Y crossing the first horizontal direction X may be arranged. A plurality of cell transistors CTR may be disposed at intersections between the plurality of bit lines BL and the plurality of word lines WL. A plurality of cell capacitors CAP may be disposed on the plurality of cell transistors CTR, respectively.

The plurality of word lines WL may include a first word line WL1 and a second word line WL2 alternately arranged in the first horizontal direction X, and the plurality of cell transistors CTR may include a first cell transistor CTR1 and a second cell transistor CTR2 arranged alternately in the first horizontal direction X. That is, the first cell transistor CTR1 may be disposed at the first word line WL1 and the second cell transistor CTR2 may be disposed at the second word line WL2.

The first cell transistor CTR1 and the second cell transistor CTR2 may have a mirror image symmetry structure with respect to each other. For example, the first cell transistor CTR1 and the second cell transistor CTR2 may have a mirror image symmetry structure with respect to a center line extending in the second horizontal direction Y.

In some example embodiments, a width of each of the plurality of bit lines BL may be 1F, and a pitch (i.e., the sum of a width and a spacing) of the plurality of bit lines BL may be 2F. Additionally, the width of each of the plurality of word lines WL may be 1F and the pitch of the plurality of word lines WL may be 2F. Accordingly, the unit area for forming one cell transistor CTR may be 4F². Accordingly, the cell transistor CTR may be of a cross point type that may require a relatively small unit area, which may be advantageous for improving integration degree of the semiconductor device 100.

A lower insulating layer 112 may be disposed on the substrate 110. In some example embodiments, the substrate 110 may include silicon, for example, single crystalline silicon, polycrystalline silicon, or amorphous silicon. In other example embodiments, the substrate 110 may include at least one selected from Ge, SiGe, SiC, GaAs, InAs, and InP. However, example embodiments are not limited thereto. In some example embodiments, the substrate 110 may include a conductive region, for example, a well doped with an impurity or a structure doped with an impurity. Additionally, the lower insulating layer 112 may include, for example, silicon oxide, silicon nitride, or a combination thereof.

A bit line BL extending in the first horizontal direction X may be disposed on the lower insulating layer 112. In some example embodiments, the bit line BL may include Ti, TiN, Ta, TaN, W, WN, TiSiN, WSiN, polysilicon, or a combination thereof. However, example embodiments are not limited thereto. For example, the bit line BL may include a conductive layer 122, a lower conductive barrier layer 124L disposed on a lower surface of the conductive layer 122, and an upper conductive barrier layer 124U disposed on a top surface of the conductive layer 122. A bit line insulating layer (not shown) extending in the first horizontal direction X may be disposed on a sidewall of the bit line BL. For example, the bit line insulating layer may fill a space between two adjacent bit lines BL and may be formed at the same height as the bit lines BL.

A mold layer 130 may be disposed on the bit line BL and the bit line insulating layer. The mold layer 130 may include a plurality of mold openings 130H. Here, each mold opening 130H may have a first sidewall 130H1 and a second sidewall 130H2 facing each other. Additionally, each mold opening 130H may have a rounded lower wall 130H3 exposing the conductive layer 122 of the bit line BL. A recess area may be formed in the bit line BL by the rounded lower wall 130H3 of each mold opening 130H. Additionally, the mold layer 130 may be disposed to cover a flat area surrounding the recess area of the bit line BL. For example, the mold layer 130 may include at least one of silicon oxide, silicon nitride, and silicon oxynitride. However, example embodiments are not limited thereto.

A plurality of channel layers 140 may be disposed on inner walls of the plurality of mold openings 130H. Each of the plurality of channel layers 140 may include a first portion 140P1 extending along the rounded lower wall 130H3 of the plurality of mold openings 130H in the first horizontal direction X and a second portion 140P2 connected to the first portion 140P1 and disposed on the first sidewall 130H1 and the second sidewall 130H2 of the plurality of mold openings 130H.

In some example embodiments, each of the plurality of channel layers 140 may have a U-shaped vertical cross-section. The first portion 140P1 of each of the plurality of channel layers 140 may have a rounded corner. The second portion 140P2 of each of the plurality of channel layers 140 may include a first sidewall 140S1 and a second sidewall 140S2 that are opposite to each other, and the second sidewall 140S2 may be in contact with the mold layer 130.

Additionally, the first portion 140P1 and the second portion 140P2 of each of the plurality of channel layers 140 may contact the bit line BL. The first portion 140P1 of each of the plurality of channel layers 140 may be in contact with the conductive layer 122, and the second portion 140P2 of each of the plurality of channel layers 140 may be in contact with a sidewall of the upper conductive barrier layer 124U. However, the plurality of channel layers 140 may not be in contact with the lower conductive barrier layer 124L.

In some example embodiments, the plurality of channel layers 140 may include an oxide semiconductor material. In some example embodiments, the oxide semiconductor material may include indium (In), for example, InGaZnOₓ (IGZO), Sn-doped InGaZnOₓ (IGZO), W-doped InGaZnOₓ (IGZO), and IZO (InZnOₓ). However, example embodiments are not limited thereto.

An intermediate insulating layer 142, a gate insulating layer 150, and a word line WL may be sequentially disposed on the first sidewall 140S1 of the channel layer 140. For example, the gate insulating layer 150 may cover the intermediate insulating layer 142 on a top surface of the first portion 140P1 and the first sidewall 140S1 of the second portion 140P2 of the channel layer 140 and arranged conformally.

The word line WL may be disposed on the top surface of the first portion 140P1 and the first sidewall 140S1 of the second portion 140P2 of the channel layer 140, and the gate insulating layer 150 may be disposed between the word line WL and the channel layer 140. Here, the gate insulating layer 150 may include an outer wall facing the first sidewall 140S1 of the channel layer 140 and an inner wall facing the word line WL.

In the semiconductor device 100 according to various example embodiments, the intermediate insulating layer 142 may be disposed between the first sidewall 140S1 of the channel layer 140 and an outer wall of the gate insulating layer 150. The intermediate insulating layer 142 may include a different type of insulating material from that of the gate insulating layer 150. For example, the intermediate insulating layer 142 may include at least one of silicon oxide and silicon oxynitride, but example embodiments are not limited thereto. In some example embodiments, the intermediate insulating layer 142 may include a double layer of silicon oxide and silicon oxynitride.

In some example embodiments, the intermediate insulating layer 142 may be formed only on a portion of the outer wall of the gate insulating layer 150. Accordingly, the outer wall of the gate insulating layer 150 may include the portion in contact with the intermediate insulating layer 142 and the remaining portion in contact with the first sidewall 140S1 of the channel layer 140. In some example embodiments, a length of the intermediate insulating layer 142 along a vertical direction Z may be substantially equal to a length of the word line WL along the vertical direction Z.

In some example embodiments, a vertical level of an uppermost surface of the intermediate insulating layer 142 may be lower than a vertical level of a lowermost surface of the contact layer 170, described below, and a vertical level of a lowermost surface of the intermediate insulating layer 142 may be higher than a vertical level of a lowermost surface of the first sidewall 140S1 of the channel layer 140. That is, the intermediate insulating layer 142 may be disposed so as not to contact the contact layer 170.

In some example embodiments, the vertical level of the uppermost surface of the intermediate insulating layer 142 may be lower than a vertical level of an uppermost surface of the second portion 140P2 of the channel layer 140, and the vertical level of the lowermost surface of the intermediate insulating layer 142 may be higher than a vertical level of an uppermost surface of the first portion 140P1 of the channel layer 140. That is, the intermediate insulating layer 142 may be disposed to contact only a portion of the first sidewall 140S1 of the channel layer 140.

A channel layer 140 having a U-shaped vertical cross-section may be disposed within one mold opening 130H, and two word lines WL may be arranged apart from each other on the channel layer 140 within one mold opening 130H. Here, one word line WL may be disposed to face one second portion 140P2 of the channel layer 140, and the other word line WL may be disposed to face another second portion 140P2 of the channel layer 140. One word line WL, one second portion 140P2 of the channel layer 140, the intermediate insulating layer 142 therebetween, and the gate insulating layer 150 may constitute the first cell transistor CTR1. In addition, another word line WL, another second portion 140P2 of the channel layer 140, the intermediate insulating layer 142 therebetween, and the gate insulating layer 150 may constitute the second cell transistor CTR2. Accordingly, the first cell transistor CTR1 and the second cell transistor CTR2 may be arranged in mirror image symmetry to each other within one mold opening 130H.

In some example embodiments, the gate insulating layer 150 may include a high-k dielectric material having a higher dielectric constant than silicon oxide. In some example embodiments, the gate insulating layer 150 may have a dielectric constant of about 10 to about 25. For example, the gate insulating layer 150 may include HfO₂, Al₂O₃, HfAlO₃, Ta₂O₃, TiO₂, or a combination thereof, but example embodiments are not limited thereto.

In some example embodiments, the word line WL may include Ti, TiN, Ta, TaN, W, WN, TiSiN, WSiN, polysilicon, or a combination thereof. However, example embodiments are not limited thereto.

The contact layer 170 may be disposed on a top surface of the channel layer 140 and a top surface of the gate insulating layer 150. The contact layer 170 may cover the channel layer 140 and the gate insulating layer 150 and may extend onto the mold layer 130. The contact layer 170 may include Ti, TiN, Ta, TaN, W, WN, TiSiN, WSiN, polysilicon, or a combination thereof. However, example embodiments are not limited thereto.

An insulating liner 182A and a first insulating layer 182B may be disposed between two word lines WL within each of the plurality of mold openings 130H, and a second insulating layer 184 may be disposed on the two word lines WL. Additionally, a third insulating layer 186 may be disposed on both sidewalls of the contact layer 170. For example, the insulating liner 182A may include silicon nitride and the first insulating layer 182B may include silicon oxide. Additionally, the second insulating layer 184 and the third insulating layer 186 may include silicon nitride. However, example embodiments are not limited thereto.

An etch stop layer 188 may be disposed on the contact layer 170 and the third insulating layer 186. The etch stop layer 188 may include an opening 188H, and the top surface of the contact layer 170 may be exposed through the opening 188H.

A capacitor structure 190 may be disposed on the etch stop layer 188. The capacitor structure 190 may include a lower electrode 192, a capacitor dielectric layer 194, and an upper electrode 196. A sidewall of a bottom portion of the lower electrode 192 may be disposed within the opening 188H of the etch stop layer 188, and the lower electrode 192 may extend in the vertical direction Z. The capacitor dielectric layer 194 may be disposed on a sidewall of the lower electrode 192, and the upper electrode 196 may cover the lower electrode 192 on the capacitor dielectric layer 194.

In order to fulfill excellent performance and improved economic efficiency, it may be required to increase the integration degree of semiconductor devices. In particular, the degree of integration of memory devices is an important factor in determining the economic feasibility of a product. Since the integration degree of a two-dimensional memory device is mainly determined by the area occupied by unit memory cells, the level of technology for forming fine patterns is a decisive factor therefor. However, as more expensive equipment may be required to form fine patterns, the area of the chip die is still limited. Thus, the integration degree of two-dimensional memory devices is still increasing to overcome the limitations of the area of the chip die. Accordingly, the demand for semiconductor devices including vertical channel transistors (VCT) is increasing.

Generally, in a semiconductor device that uses an oxide semiconductor material containing indium (In) as a channel layer constituting a vertical channel transistor, a gate insulating layer includes a high-k dielectric material to improve electrical characteristics. In this way, when a high-k dielectric material is used as the gate insulating layer, electrical characteristics such as on-current are improved, but electron trapping on an interface between a channel layer (oxide semiconductor material) and the gate insulating layer (high-k dielectric material) is increasing. Accordingly, problems such as a decrease in thermal stability and/or product reliability may occur in semiconductor devices.

To solve this problem, in the semiconductor device 100 according to various example embodiments of the inventive concepts, by inserting the intermediate insulating layer 142 including silicon oxide and/or silicon oxynitride between the first sidewall 140S1 of the channel layer 140 and the outer wall of the gate insulating layer 150, the problem of the decrease in thermal stability and product reliability of the semiconductor device 100 may be more efficiently controlled.

Ultimately, compared to high-k dielectric materials, silicon oxide and/or silicon oxynitride, which has a relatively small effect of electron trapping with respect to oxide semiconductor materials, that is, the intermediate insulating layer 142, is arranged on a portion of the channel layer 140, and thus the semiconductor device 100 which has improved electrical characteristics and also improved product reliability at the same time may be provided.

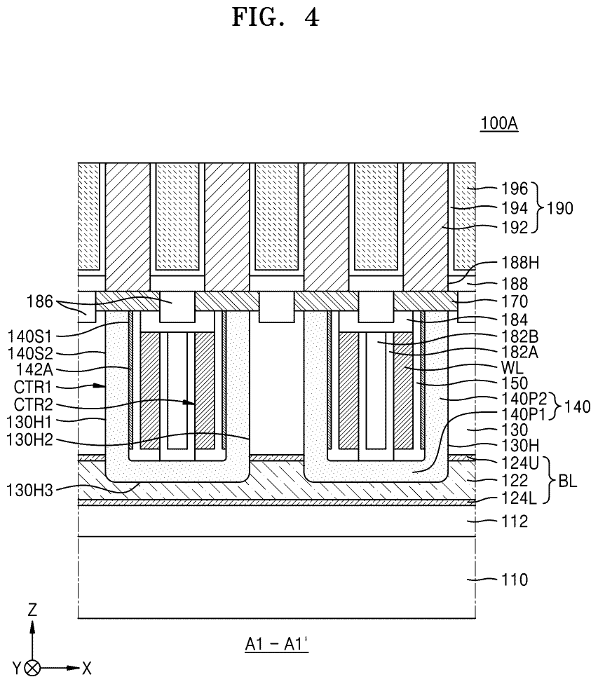

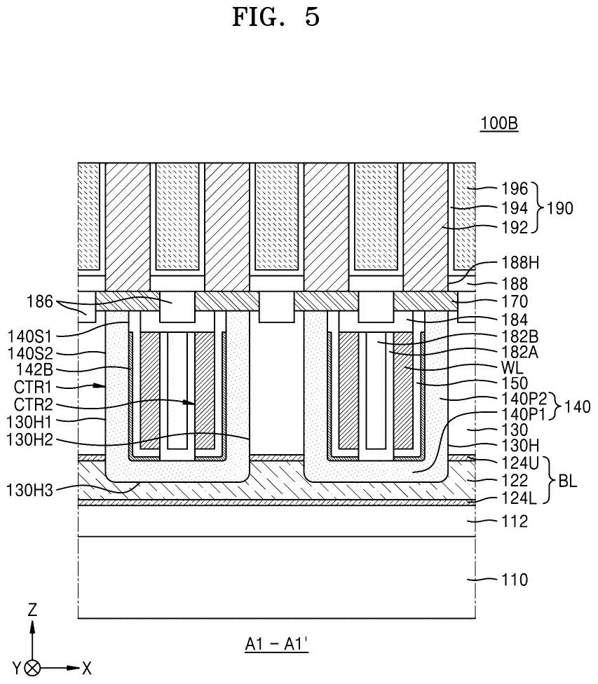

FIGS. 4 and 5 are cross-sectional views illustrating a semiconductor device according to other example embodiments.

Most of the components constituting semiconductor devices 100A and 100B described below and the materials forming the components are substantially the same or similar to those previously described with reference to FIGS. 1 to 3. Thus, for convenience of description, the description will focus on the differences from the semiconductor device 100 described above.

Referring to FIG. 4, the semiconductor device 100A may include a bit line BL, a word line WL, a channel layer 140, an intermediate insulating layer 142A, a gate insulating layer 150, a contact layer 170, and a capacitor structure 190.

In the semiconductor device 100A according to various example embodiments, the intermediate insulating layer 142A may be arranged between the first sidewall 140S1 of the channel layer 140 and the outer wall of the gate insulating layer 150. The intermediate insulating layer 142A may include a different type of insulating material from the gate insulating layer 150. For example, the intermediate insulating layer 142A may include at least one of silicon oxide and silicon oxynitride, but example embodiments are not limited thereto. In some example embodiments, the intermediate insulating layer 142A may include a double layer of silicon oxide and silicon oxynitride.

In some example embodiments, the intermediate insulating layer 142A may be formed only on a portion of the outer wall of the gate insulating layer 150. Accordingly, the outer wall of the gate insulating layer 150 may include the portion in contact with the intermediate insulating layer 142A and the remaining portion in contact with the first sidewall 140S1 of the channel layer 140. In some example embodiments, a length of the intermediate insulating layer 142A in the vertical direction Z may be greater than a length of the word line WL in the vertical direction Z.

In some example embodiments, a vertical level of an uppermost surface of the intermediate insulating layer 142A may be equal to the vertical level of the lowermost surface of the contact layer 170, and a vertical level of a lowermost surface of the intermediate insulating layer 142A may be higher than the vertical level of the lowermost surface of the first sidewall 140S1 of the channel layer 140. That is, the intermediate insulating layer 142A may be disposed to contact the contact layer 170.

In some example embodiments, the vertical level of the uppermost surface of the intermediate insulating layer 142A may be equal to the vertical level of the uppermost surface of the second portion 140P2 of the channel layer 140, and the vertical level of the lowermost surface of the intermediate insulating layer 142A may be higher than the vertical level of the uppermost surface of the first portion 140P1 of the channel layer 140. That is, the intermediate insulating layer 142A may be disposed to contact most of the first sidewall 140S1 of the channel layer 140.

Referring to FIG. 5, the semiconductor device 100B may include a bit line BL, a word line WL, a channel layer 140, an intermediate insulating layer 142B, a gate insulating layer 150, a contact layer 170, and a capacitor structure 190.

In the semiconductor device 100B according to various example embodiments, the intermediate insulating layer 142B may be arranged between the first sidewall 140S1 of the channel layer 140 and the outer wall of the gate insulating layer 150. The intermediate insulating layer 142B may include a different type of insulating material from that of the gate insulating layer 150. For example, the intermediate insulating layer 142B may include at least one of silicon oxide and silicon oxynitride, but example embodiments are not limited thereto. In some example embodiments, the intermediate insulating layer 142B may include a double layer of silicon oxide and silicon oxynitride.

In some example embodiments, the intermediate insulating layer 142B may be formed only on a portion of the outer wall of the gate insulating layer 150. Accordingly, the outer wall of the gate insulating layer 150 may include the portion in contact with the intermediate insulating layer 142B and the remaining portion in contact with the first sidewall 140S1 of the channel layer 140. In some example embodiments, a length of the intermediate insulating layer 142B in the vertical direction Z may be greater than a length of the word line WL in the vertical direction Z.

In some example embodiments, a vertical level of an uppermost surface of the intermediate insulating layer 142B may be lower than the vertical level of the lowermost surface of the contact layer 170, and a vertical level of a lowermost surface of the intermediate insulating layer 142B may be equal to the vertical level of the uppermost surface of the first portion 140P1 of the channel layer 140. That is, the intermediate insulating layer 142B may be disposed so as not to contact the contact layer 170.

In some example embodiments, the vertical level of the uppermost surface of the intermediate insulating layer 142B may be lower than the vertical level of the uppermost surface of the second portion 140P2 of the channel layer 140, and a lower surface of the intermediate insulating layer 142B may be disposed in the first horizontal direction X to contact the top surface of the first portion 140P1 of the channel layer 140. That is, the intermediate insulating layer 142B may be disposed to face both one sidewall and a lower surface of the word line WL.

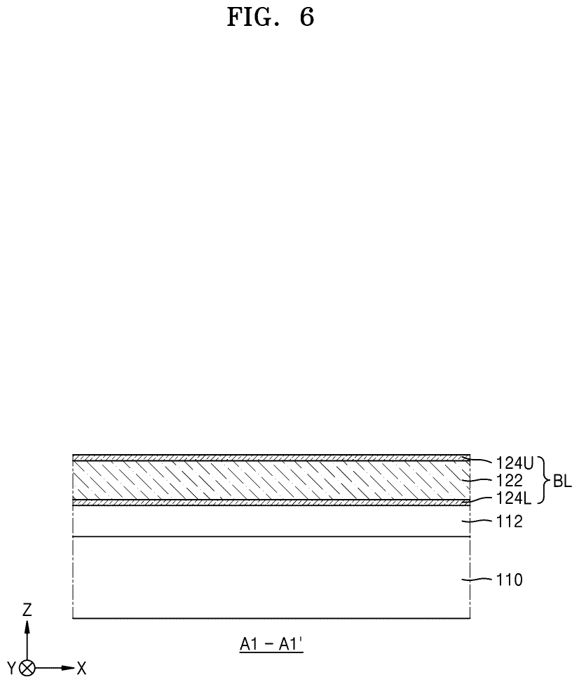

FIGS. 6 to 16 are cross-sectional views illustrating a method of manufacturing a semiconductor device, according to a process sequence, according to various example embodiments.

Referring to FIG. 6, a lower insulating layer 112 may be formed on a substrate 110.

Next, a plurality of bit lines BL extending in a first horizontal direction X and a bit line insulating layer (not shown) which fills a space between the plurality of bit lines BL may be formed on the lower insulating layer 112.

In some example embodiments, each of the plurality of bit lines BL may include a lower conductive barrier layer 124L, a conductive layer 122, and an upper conductive barrier layer 124U arranged sequentially. For example, a bit line formation space (not shown) may be formed by forming the bit line insulating layer on the lower insulating layer 112 and patterning the bit line insulating layer by using a mask pattern (not shown), and the lower conductive barrier layer 124L, the conductive layer 122, and the upper conductive barrier layer 124U may be sequentially formed in the bit line formation space.

Next, the plurality of bit lines BL may be formed by removing portions of the lower conductive barrier layer 124L, the conductive layer 122, and the upper conductive barrier layer 124U formed on the top surface of the bit line insulating layer so that a top surface of the bit line insulating layer is exposed.

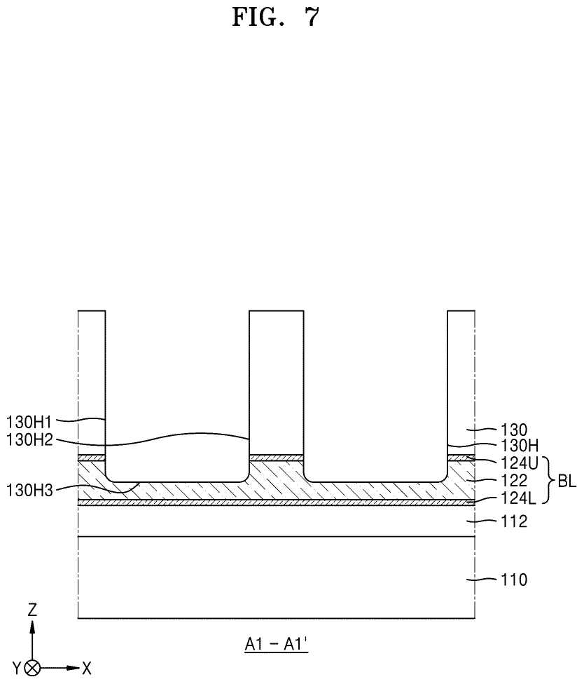

Referring to FIG. 7, a mold layer 130 may be formed on the plurality of bit lines BL and the bit line insulating layer.

The mold layer 130 may be formed using at least one of silicon oxide, silicon nitride, and silicon oxynitride, however, example embodiments are not limited thereto, and the mold layer 130 may have a relatively large height in the vertical direction Z.

Next, a mask pattern (not shown) may be formed on the mold layer 130, and a plurality of mold openings 130H may be formed using the mask pattern as an etch mask. Each mold opening 130H may have a first sidewall 130H1 and a second sidewall 130H2 facing each other. Additionally, each mold opening 130H may have a rounded lower wall 130H3 exposing the conductive layer 122 of the bit line BL. A recess area may be formed in the bit line BL by the rounded lower wall 130H3 of each mold opening 130H.

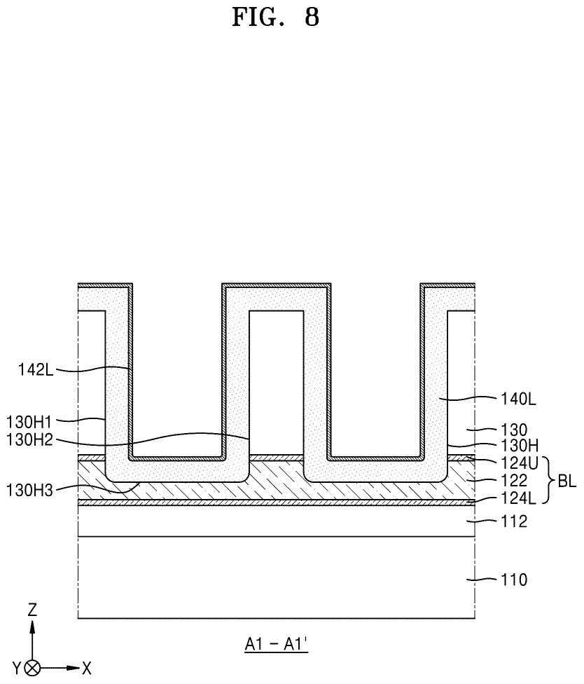

Referring to FIG. 8, a preliminary channel layer 140L may be formed on the mold layer 130 to conformally cover an inner wall of the mold opening 130H.

In some example embodiments, the preliminary channel layer 140L may be formed using an oxide semiconductor material. The oxide semiconductor material may include indium (In), for example, InGaZnOₓ (IGZO), Sn-doped InGaZnOₓ (IGZO), W-doped InGaZnOₓ (IGZO), and InZnOₓ (IZO). However, example embodiments are not limited thereto.

In some example embodiments, the preliminary channel layer 140L may be formed using at least one of a chemical vapor deposition (CVD) process, a low pressure CVD process, a plasma enhanced CVD process, a metal organic CVD (MOCVD) process, and an atomic layer deposition process. However, example embodiments are not limited thereto.

Next, a preliminary intermediate insulating layer 142L may be conformally formed on the preliminary channel layer 140L. In some example embodiments, the preliminary intermediate insulating layer 142L may be formed using silicon oxide and/or silicon oxynitride.

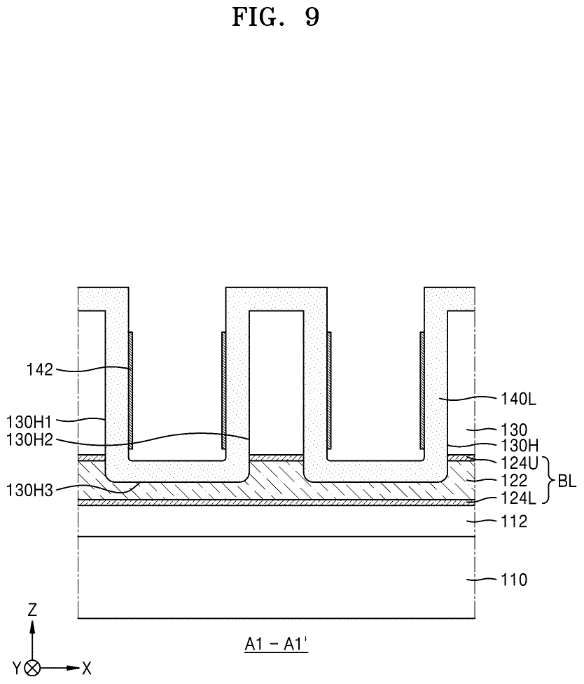

Referring to FIG. 9, a portion of the preliminary intermediate insulating layer 142L (see FIG. 8) may be etched to form an intermediate insulating layer 142 on a sidewall of the preliminary channel layer 140L.

By patterning the preliminary intermediate insulating layer 142L using a mask pattern (not shown), the intermediate insulating layer 142 may be left only on a desired area of the preliminary channel layer 140L.

In some example embodiments, a vertical level of an uppermost surface of the intermediate insulating layer 142 may be lower than a vertical level of an uppermost surface of the mold opening 130H, and a vertical level of a lowermost surface of the intermediate insulating layer 142 may be higher than a vertical level of a top surface of a bottom portion of the preliminary channel layer 140L. That is, the intermediate insulating layer 142 may be formed to contact only a portion of the sidewall of the preliminary channel layer 140L.

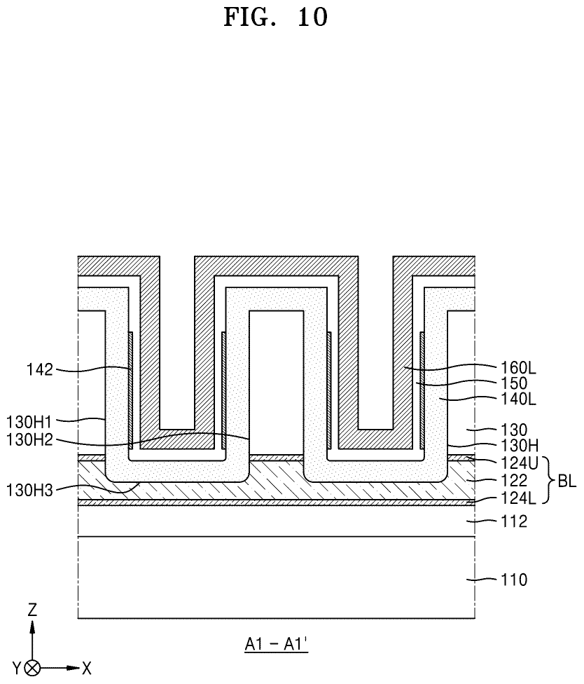

Referring to FIG. 10, a gate insulating layer 150 and a gate electrode layer 160L may be sequentially formed on the preliminary channel layer 140L to cover the intermediate insulating layer 142.

The gate insulating layer 150 may include a high-k dielectric material having a higher dielectric constant than silicon oxide. That is, the intermediate insulating layer 142 may include a different type of insulating material from that of the gate insulating layer 150.

In some example embodiments, the gate electrode layer 160L may be formed using Ti, TiN, Ta, TaN, W, WN, TiSiN, WSiN, polysilicon, or a combination thereof. However, example embodiments are not limited thereto.

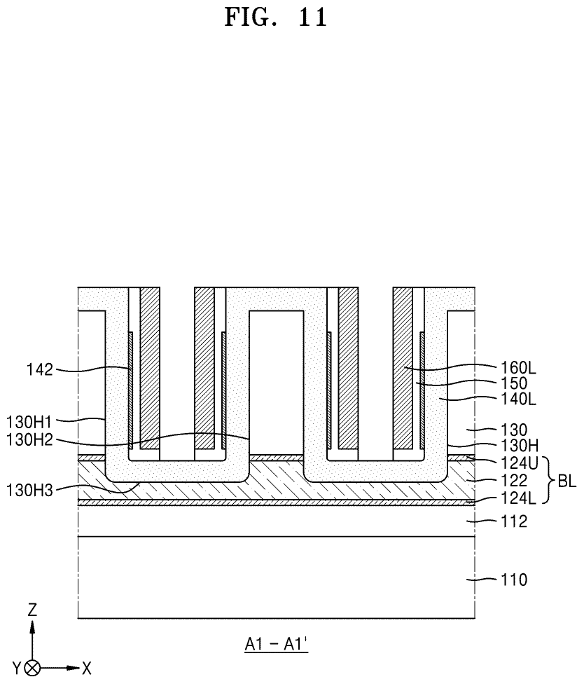

Referring to FIG. 11, an anisotropic etching process may be performed on the gate electrode layer 160L to remove a portion of the gate electrode layer 160L disposed on a bottom portion of the mold opening 130H, and the gate electrode layer 160L may be left on the first sidewall 130H1 and the second sidewall 130H2 of the mold opening 130H.

In addition, a portion of the gate electrode layer 160L disposed on a top surface of the mold layer 130 may be removed by the anisotropic etching process.

For example, the gate electrode layer 160L may be divided into two word lines WL respectively disposed on the first sidewall 130H1 and the second sidewall 130H2 of the plurality of mold openings 130H.

Furthermore, a portion of the gate insulating layer 150 disposed on the bottom portion of the mold opening 130H may be removed by the anisotropic etching process. As a result, a top surface of the preliminary channel layer 140L may be exposed on the bottom portion of the mold opening 130H. Additionally, by the anisotropic etching process, a portion of the gate insulating layer 150 disposed on the top surface of the mold layer 130 may be removed and the top surface of the preliminary channel layer 140L may be exposed.

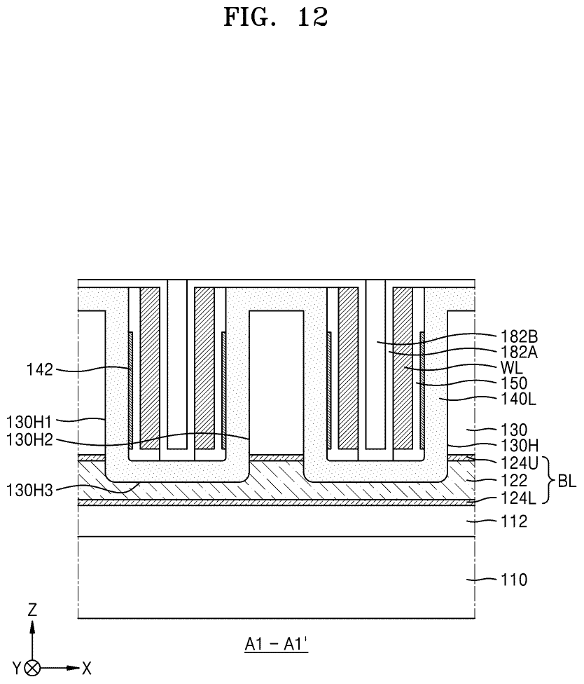

Referring to FIG. 12, an insulating liner 182A and a first insulating layer 182B may be formed inside the mold opening 130H.

The insulating liner 182A and the first insulating layer 182B may be disposed between two adjacent word lines WL, and the insulating liner 182A may be disposed on the top surface of the preliminary channel layer 140L.

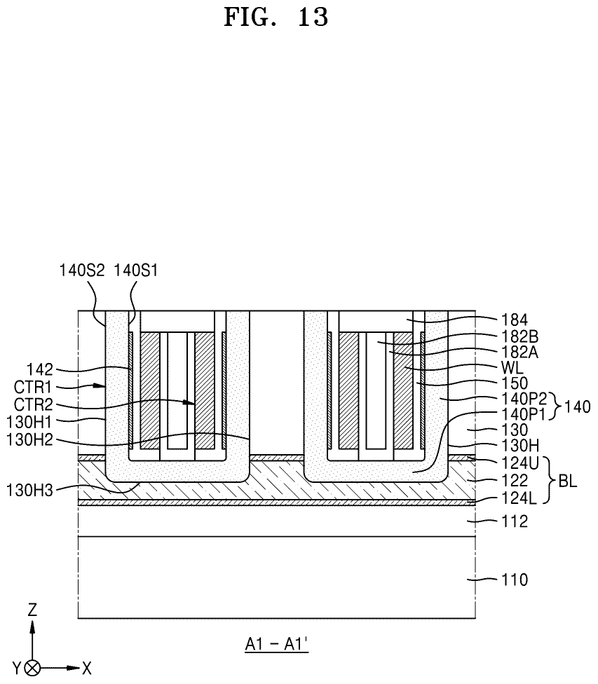

Referring to FIG. 13, a portion of the insulating liner 182A disposed on the top surface of the mold layer 130 and a portion of the preliminary channel layer 140L disposed on the top surface of the mold layer 130 may be removed by an etch-back process or a planarization process to form the channel layer 140 within the mold opening 130H.

The channel layer 140 having a U-shaped vertical cross-section may be formed within the mold opening 130H through the etch-back process or the planarization process. Additionally, as the portion of the preliminary channel layer 140L disposed on the top surface of the mold layer 130 is removed, the top surface of the mold layer 130 may be exposed.

In some example embodiments, the channel layer 140 may include the first portion 140P1 extending in the first horizontal direction X, and the second portion 140P2 connected to both ends of the first portion 140P1 and extending in the vertical direction Z. The first sidewall 140S1 of the second portion 140P2 may be surrounded by the intermediate insulating layer 142 and the gate insulating layer 150, and the second sidewall 140S2 of the second portion 140P2 may be surrounded by the mold layer 130. Additionally, a top surface of the channel layer 140 may be at the same vertical level as the top surface of the mold layer 130.

Next, an upper portion of the word line WL disposed within the mold opening 130H may be removed through an etch-back process. In the etch-back process, an upper portion of the insulating liner 182A and an upper portion of the first insulating layer 182B may be removed together.

Next, the second insulating layer 184 may be formed to fill the entrance of the mold opening 130H. The second insulating layer 184 may be disposed with a flat bottom surface on top surfaces of the word line WL, the insulating liner 182A, and the first insulating layer 182B.

Accordingly, the first cell transistor CTR1 and the second cell transistor CTR2 may be formed within the mold opening 130H. The first cell transistor CTR1 and the second cell transistor CTR2 may be arranged in mirror image symmetry with respect to each other.

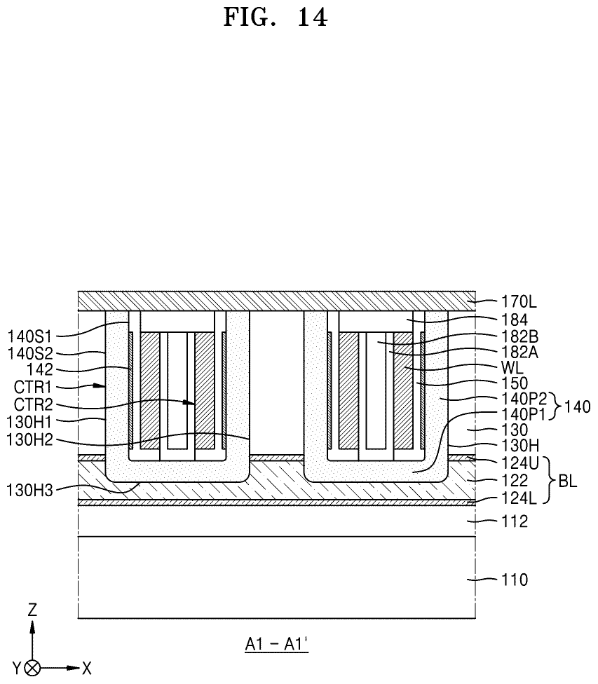

Referring to FIG. 14, a contact conductive layer 170L may be formed on the mold layer 130 and the second insulating layer 184.

In some example embodiments, the contact conductive layer 170L may include Ti, TiN, Ta, TaN, W, WN, TiSiN, WSiN, polysilicon, or a combination thereof. However, example embodiments are not limited thereto.

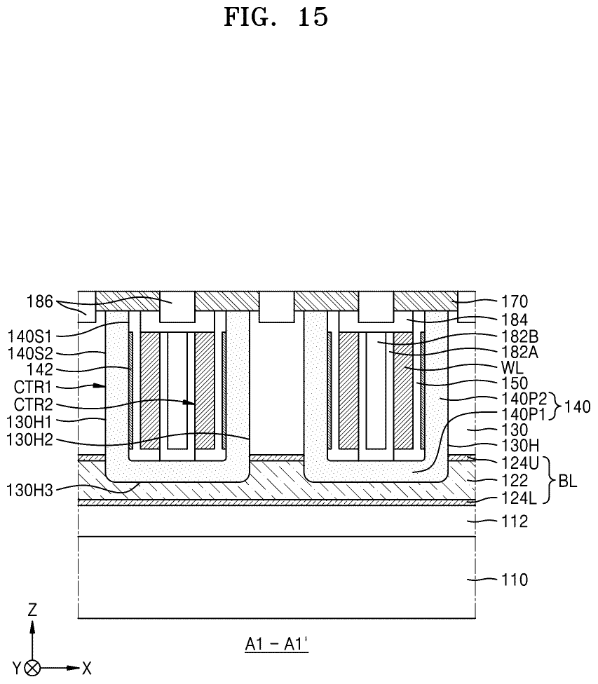

Referring to FIG. 15, a mask pattern (not shown) may be formed on the contact conductive layer 170L (see FIG. 14), and a portion of the contact conductive layer 170L may be removed using the mask pattern to form the contact layer 170, and the third insulating layer 186 may be formed in a region from which the contact conductive layer 170L has been removed.

In some example embodiments, the third insulating layer 186 may be formed using silicon nitride. However, example embodiments are not limited thereto. In addition, a sidewall of the contact layer 170 may be surrounded by the third insulating layer 186, and a bottom surface of the contact layer 170 may cover the top surface of the channel layer 140 and the top surface of the gate insulating layer 150 to extend onto the mold layer 130.

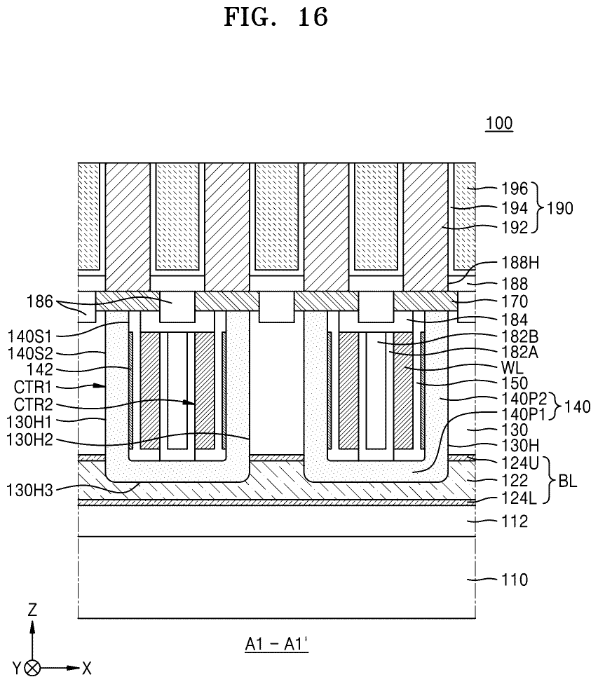

Referring to FIG. 16, the etch stop layer 188 may be formed on the contact layer 170 and the third insulating layer 186. The etch stop layer 188 may include an opening 188H, and the top surface of the contact layer 170 may be exposed through the opening 188H.

Next, the lower electrode 192, the capacitor dielectric layer 194, and the upper electrode 196 may be sequentially formed on the etch stop layer 188.

By performing the manufacturing process described above, the semiconductor device 100, according to various example embodiments of the inventive concepts, may be manufactured.

The semiconductor device 100A described with reference to FIG. 4 may be manufactured by setting the vertical level of the uppermost surface of the intermediate insulating layer 142 to be substantially the same as the vertical level of the uppermost surface of the preliminary channel layer 140L, and setting the vertical level of the lowermost surface of the intermediate insulating layer 142 to be higher than the vertical level of the top surface of the bottom portion of the preliminary channel layer 140L in FIG. 9.

Alternatively, the semiconductor device 100B described with reference to FIG. 5 may be manufactured by setting the vertical level of the uppermost surface of the intermediate insulating layer 142 to be lower than the vertical level of the uppermost surface of the mold opening 130H, and forming the lower surface of the intermediate insulating layer 142 along the top surface of the bottom portion of the preliminary channel layer 140L in FIG. 9.

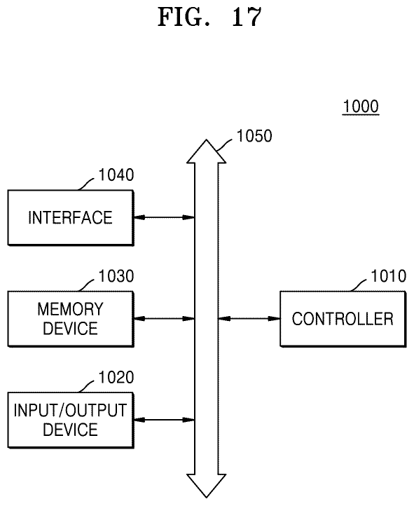

FIG. 17 is a structural diagram illustrating a system including a semiconductor device, according to various example embodiments.

Referring to FIG. 17, a system 1000 includes a controller 1010, an input/output device 1020, a memory device 1030, an interface 1040, and a bus 1050.

The system 1000 may be a mobile system or a system that transmits or receives information. In some example embodiments, the mobile system may be a portable computer, a web tablet, a mobile phone, a digital music player, or a memory card.

The controller 1010 is for controlling an execution program in the system 1000 and may include a microprocessor, a digital signal processor, a microcontroller, or a similar device.

The input/output device 1020 may be used to input or output data of the system 1000. The system 1000 may be connected to an external device, for example, a personal computer or a network, using the input/output device 1020, and may exchange data with the external device. The input/output device 1020 may be, for example, a touch screen, touch pad, keyboard, or display.

The memory device 1030 may store data for the operation of the controller 1010 or store data processed by the controller 1010. The memory device 1030 may include any one of the semiconductor devices 100, 100A, and 100B according to various example embodiments of the inventive concepts described above.

The interface 1040 may be a data transmission path between the system 1000 and an external device. The controller 1010, the input/output device 1020, the memory device 1030, and the interface 1040 may communicate with each other via the bus 1050.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

It should be understood that various example embodiments described herein should be considered in a descriptive sense only and not for purposes of limitation. Descriptions of features or aspects within each embodiment should typically be considered as available for other similar features or aspects in other example embodiments; example embodiments are not necessarily mutually exclusive with one another. While one or more example embodiments have been described with reference to the figures, it will be understood by those of ordinary skill in the art that various changes in form and details may be made therein without departing from the spirit and scope as defined by the following claims.

While various example embodiments of the inventive concepts have been particularly shown and described with reference to various example embodiments thereof, it will be understood by those skilled in the art that various changes in form and details may be made therein without departing from the spirit and scope of the inventive concepts as defined by the appended claims. The example embodiments should thus be considered in a descriptive sense only and not for purposes of limitation.

What is claimed is:

1. A semiconductor device comprising:
a bit line extending in a first horizontal direction on a substrate;
a channel layer on the bit line and penetrating into a portion of the bit line, including an oxide semiconductor material including indium (In), and the channel layer having an inner wall and an outer wall;
a gate insulating layer on one side of an inner wall of the channel layer, and the gate insulating layer having an inner wall and an outer wall;
an intermediate insulating layer between the inner wall of the channel layer and the outer wall of the gate insulating layer and including an insulating material that is different from that of the gate insulating layer;
a word line on the inner wall of the gate insulating layer and extending in a second horizontal direction intersecting with the first horizontal direction; and
a contact layer on a top surface of the channel layer and a top surface of the gate insulating layer,
wherein the intermediate insulating layer is formed only on a portion of the outer wall of the gate insulating layer.

2. The semiconductor device of claim 1, wherein the oxide semiconductor material comprises at least one of InGaZnOₓ (IGZO) and InZnOₓ (IZO),
the gate insulating layer comprises a high-k dielectric material, and
the intermediate insulating layer comprises at least one of silicon oxide and silicon oxynitride.

3. The semiconductor device of claim 1, wherein a vertical level of an uppermost surface of the intermediate insulating layer is lower than a vertical level of a lowermost surface of the contact layer, and
a vertical level of a lowermost surface of the intermediate insulating layer is higher than a vertical level of a lowermost surface of the inner wall of the channel layer.

4. The semiconductor device of claim 3, wherein a length of the intermediate insulating layer in a vertical direction is equal to a length of the word line in the vertical direction.

5. The semiconductor device of claim 1, wherein an uppermost surface of the intermediate insulating layer is in contact with a lowermost surface of the contact layer, and
a vertical level of a lowermost surface of the intermediate insulating layer is higher than a vertical level of a lowermost surface of the inner wall of the channel layer.

6. The semiconductor device of claim 5, wherein a length of the intermediate insulating layer in a vertical direction is greater than a length of the word line in the vertical direction.

7. The semiconductor device of claim 1, wherein a vertical level of an uppermost surface of the intermediate insulating layer is lower than a vertical level of a lowermost surface of the contact layer, and
a lowermost surface of the intermediate insulating layer is in contact with a lowermost surface of the inner wall of the channel layer.

8. The semiconductor device of claim 7, wherein the intermediate insulating layer faces both one sidewall and a lower surface of the word line.

9. The semiconductor device of claim 1, wherein the bit line comprises a lower conductive barrier layer, a conductive layer, and an upper conductive barrier layer arranged sequentially, and
the outer wall of the channel layer contacts a sidewall of the upper conductive barrier layer and the conductive layer but not the lower conductive barrier layer.

10. The semiconductor device of claim 9, wherein a portion of the outer wall of the channel layer in contact with the conductive layer has rounded corners.

11. A semiconductor device comprising:
a bit line extending in a first horizontal direction on a substrate;
a channel layer having a U-shape and penetrating into a portion of the bit line, including InGaZnOₓ (IGZO), and having an inner wall and an outer wall;
a gate insulating layer on one side of the inner wall of the channel layer, comprising a high-k dielectric material, and the gate insulating layer having an inner wall and an outer wall;
an intermediate insulating layer between the inner wall of the channel layer and the outer wall of the gate insulating layer, and the intermediate insulating layer including at least one of silicon oxide and silicon oxynitride;
a word line on the inner wall of the gate insulating layer and extending in a second horizontal direction intersecting with the first horizontal direction; and
a contact layer on a top surface of the channel layer and a top surface of the gate insulating layer.

12. The semiconductor device of claim 11, wherein the intermediate insulating layer is formed only on a portion of the outer wall of the gate insulating layer, and
the outer wall of the gate insulating layer includes a portion contacting the intermediate insulating layer and the remaining portion contacting the inner wall of the channel layer.

13. The semiconductor device of claim 12, wherein a length of the intermediate insulating layer in a vertical direction is equal to a length of the word line in the vertical direction.

14. The semiconductor device of claim 12, wherein a length of the intermediate insulating layer in a vertical direction is greater than a length of the word line in the vertical direction.

15. The semiconductor device of claim 11, wherein the bit line includes a recess area and a flat area surrounding the recess area,
the semiconductor device further comprises a mold layer covering the flat area of the bit line, and
the outer wall of the channel layer is contacting a sidewall of the mold layer and the recess area of the bit line.

16. A semiconductor device comprising:
a bit line extending in a first horizontal direction on a substrate;
a mold layer covering the bit line on the substrate and the mold layer having a mold opening;
a channel layer on an inner wall of the mold opening, having a bottom portion penetrating into the bit line and a sidewall portion extending in a vertical direction on the inner wall of the mold opening, and the channel layer including InGaZnOₓ (IGZO);
a gate insulating layer within the mold opening, on the channel layer, and the gate insulating layer comprising a high-k dielectric material;
an intermediate insulating layer within the mold opening, between the channel layer and the gate insulating layer, and the intermediate insulating layer comprising at least one of silicon oxide and silicon oxynitride;
a word line within the mold opening, on the gate insulating layer, and extending in a second horizontal direction intersecting with the first horizontal direction;
a contact layer on a top surface of the channel layer and a top surface of the gate insulating layer; and
a capacitor structure on the contact layer,
wherein the intermediate insulating layer is formed only in a portion between the channel layer and the gate insulating layer.

17. The semiconductor device of claim 16, wherein a vertical level of an uppermost surface of the intermediate insulating layer is lower than a vertical level of an uppermost surface of the sidewall portion of the channel layer, and
a vertical level of a lowermost surface of the intermediate insulating layer is higher than a vertical level of an uppermost surface of the bottom portion of the channel layer.

18. The semiconductor device of claim 16, wherein a vertical level of an uppermost surface of the intermediate insulating layer is equal to a vertical level of an uppermost surface of the sidewall portion of the channel layer, and
a vertical level of a lowermost surface of the intermediate insulating layer is higher than a vertical level of an uppermost surface of the bottom portion of the channel layer.

19. The semiconductor device of claim 16, wherein a vertical level of an uppermost surface of the intermediate insulating layer is lower than a vertical level of an uppermost surface of the sidewall portion of the channel layer, and
a vertical level of a lowermost surface of the intermediate insulating layer is equal to a vertical level of an uppermost surface of the bottom portion of the channel layer.

20. The semiconductor device of claim 16, wherein the bit line comprises a recess area, and
the bottom portion of the channel layer fills the recess area of the bit line.
